(19) United States
(12) Patent Application Publication
(10) Pub. No.: US 2006/0255451 A1
(43) Pub. Date: Nov. 16, 2006

(54) Heat Conduction Interface Method and Manufacturing Method Thereof

(76) Inventors: Ming-Hang Hwang, Taipei City (TW); Yu-Chiang Cheng, Taipei City (TW); Chao-Yi Chen, Taipei City (TW); Hsin-Lung Kuo, Taipei City (TW); Bin-Wei Lee, Taipei City (TW); Wei-Chung Hsiao, Taipei City (TW)

Correspondence Address: LAW OFFICES OF LAI & ASSOCIATES, P.C., 5800 RANCHESTER, STE. 200, HOUSTON, TX, 77036, US

(21) Appl. No.: 11/307,850

(22) Filed: Feb. 24, 2006

(30) Foreign Application Priority Data
Mar. 21, 2005 (TW) 94108676

(51) Int. Cl. H01L 23/34

(52) U.S. Cl. 257/713

(57) ABSTRACT

This invention discloses a manufacturing process method and a structure for a heat conduction interface material. This heat conduction interface material is often used as a buffer interface between chips and heat dissipation devices and is conducted the waste heat from the chips. The heat conduction interface material can be combined a plastic material and a bracket structure of carbon element. The corresponding manufacturing process method for this heat conduction interface material comprises a mixed process that is composed of a plastic material and a bracket structure of carbon element. The bracket structure of carbon element has high thermal conductivity, so as to improve the efficiency of heat conduction. The bracket structure of carbon element can be mixed into the metal and resins.

### FIELD OF THE INVENTION

The present invention relates to a heat conduction interface material and corresponding manufacturing methods and, more particularly, to employ a mixture to form a heat conduction interface material having a plastic material and a bracket structure of carbon element.

### BACKGROUND OF THE INVENTION

In recent years, the pace of high technology industry development is extremely fast, the development of electronic components is toward small volumes and high densities, especially for chips. The chips are a core and the waste heat caused by high temperature, which is generated from resonances, is increased because the working clocks of the chip are raised. The performance of the chips will be decreased if the waste heat is unable to eliminate appropriately. Therefore, various heat conduction materials are provided to improve the efficiency of heat dissipation.

In the prior art, the material applying in the heat dissipation structure usually includes copper or aluminum to be the tendency of current heat dissipation technique. However, in heat conduction process, the heat conduction material needs to be covered a surface of a chip to absorb the waste heat caused by high temperature, which is generated from the operation of the chip. Although the thermal conductivity of copper is twice as greater than aluminum and is a good heat conductor, a heat conduction element composed by copper can not be covered the surface of the chip directly, a heat dissipation slip for example. Because the surface of the heat dissipation slip looks like smoothly, the reality is that the surface is rough without smooth. The rough surface of the heat dissipation slip can not be contacted the surface of the chip completely that produces slight gaps and is unable to absorb the waste heat generated from the chip effectively. Therefore, an interface is required to fill above slight gaps in order to conduct the waste heat to the heat dissipation slip or other heat dissipation devices. Currently, the interface usually uses thermal grease which is composed of silicon and the thermal grease has better heat conduction performance and stickiness. Another interface is a heat dissipation patch which is made by aluminum and the heat dissipation patch can be covered the surface of the chip completely. Above heat conduction interface materials and corresponding heat conductions are described as follows.

Referring to FIG. 1, a schematic diagram illustrates relations between a heat dissipation patch and other components. The heat dissipation patch 11 is made by aluminum and has an upper surface 111 for pasting a heat dissipation slip 12. The heat dissipation patch 11 has a lower surface 112 which corresponds to the upper surface 111 for binding a cover surface 131 of a chip 13. In another word, the heat dissipation slip 12 can be adhered to the cover surface 131 of the chip 13 via the heat dissipation patch 11. That is one of conventional heat conduction interfaces.

Referring to FIG. 2, a schematic diagram illustrates relations between thermal grease and other components. The thermal grease 21 is composed of silicon and has better heat conduction performance and stickiness. The thermal grease 21 is coated on the cover surface 131 of the chip 13 as shown in FIG. 1 to form a thin film that enables the heat dissipation slip 12 as shown in FIG. 1 to adhere to the cover surface 131 of the chip 13 by the thermal grease 21. Therefore, the heat conduction for above heat interfaces is that the waste heat caused by high temperature, which is generated from the operation of the chip 13, is conducted by the cover surface 131 of the chip 13 to the heat dissipation patch 11 or the thermal grease 21 first. The waste heat is then conducted to the heat dissipation slip 12 when the heat dissipation patch 11 or the thermal grease 21 absorbs the waste heat.

However, the heat dissipation patch formed by aluminum has limited thermal conductivity that may experience a bottleneck and is unable to satisfy the high heat conduction generated from the fast development of the chip. The thermal grease composed of silicon has limited lifetime that needs to be replaced periodically. A qualitative change may be produced for the thermal grease that causes hardening or becomes dust easily while in the high temperature environment. Accordingly, a material with high thermal conductivity is needed to apply for a heat conduction interface in conducting the waste heat.

Besides, diamonds are well known and have characteristics with the highest hardness, the fastest heat conduction, and the widest refraction range in current materials. Diamonds, therefore, are always one of more important materials in engineering due to the excellent characteristics. The thermal conductivity of diamonds at the normal atmospheric temperature is five times more than copper. Moreover, the thermal expansion factor of diamonds at high temperature is very small that shows the excellent efficiency for heat dissipating. The feature may help people to differentiate the adulteration of diamonds. In the prior art, many technologies and manufacture procedures have been developed to make diamonds. The direct decomposition for hydrocarbons is the most familiar method like Microwave Plasma Enhance Chemical Vapor Deposition (MPCVD) and Hot Filament CVD (HFCVD). By the aforesaid methods, polycrystalline diamond films can be deposited. The characteristic of the polycrystalline diamond films is same as the single crystal diamonds.

### SUMMARY OF THE INVENTION

Briefly, to eliminate the waste heat generated by electronic components efficiently and to face the development tendency of electronic components with small volumes and high densities, the object of the present invention is to provide a heat conduction interface material which is applied for pasting to a surface of a chip. The heat conduction interface material is also connected to a heat dissipation slip to conduct the waste heat caused by high temperature which is generated by the operation of the chip that improves the efficiency of heat conduction. Moreover, the heat conduction interface material provided by the present invention is not only restricted to apply for the waste heat conduction between the heat dissipation slip and the chip, but is also applied for other heat conduction appliances.

In accordance with the present invention a heat conduction interface material is applied to a buffer interface between a chip and a heat dissipation slip and is combined with a plastic material and a bracket structure of carbon element. The plastic material is copper plastic material or aluminum plastic material or resins or other metal plastic material with high thermal conductivity. The bracket structure of carbon element is diamonds and the bracket structure of carbon element can be coated on a surface of the metal plastic material or the resins or can be mixed into the metal plastic material or resins.

Other features and advantages of the present invention and variations thereof will become apparent from the following description, drawings, and claims.

### BRIEF DESCRIPTION OF DRAWINGS

FIG. 1 is a schematic diagram illustrating relations between a heat dissipation patch and other components;

FIG. 2 is a schematic diagram illustrating relations between thermal grease and other components;

FIG. 3 is a schematic diagram illustrating a mixture forming semi-finished goods for a heat conduction interface material having a plastic material and a bracket structure according to an embodiment of the present invention;

FIG. 4 is a schematic diagram illustrating forming a flat piece of a heat conduction interface material according to an embodiment of the present invention; and

FIG. 5 is a flowchart illustrating a manufacturing process for making a heat conduction interface material according to an embodiment of the present invention.

### DETAILED DESCRIPTION OF THE PREFERRED EMBODIMENTS

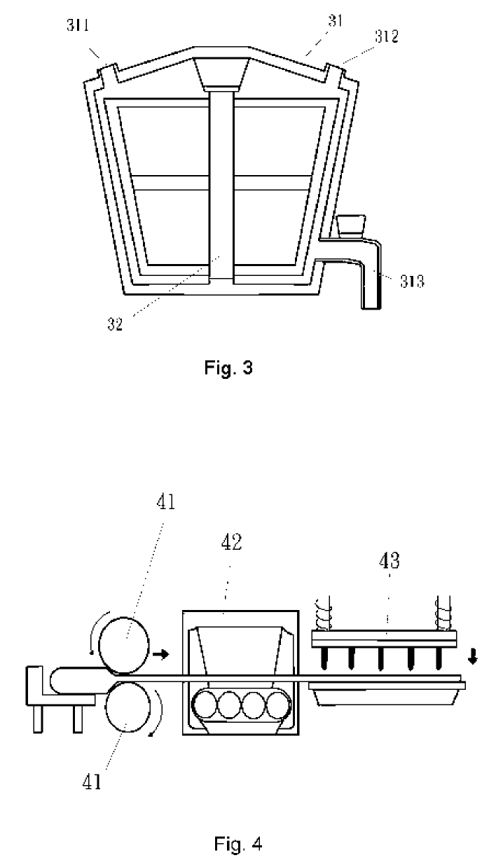

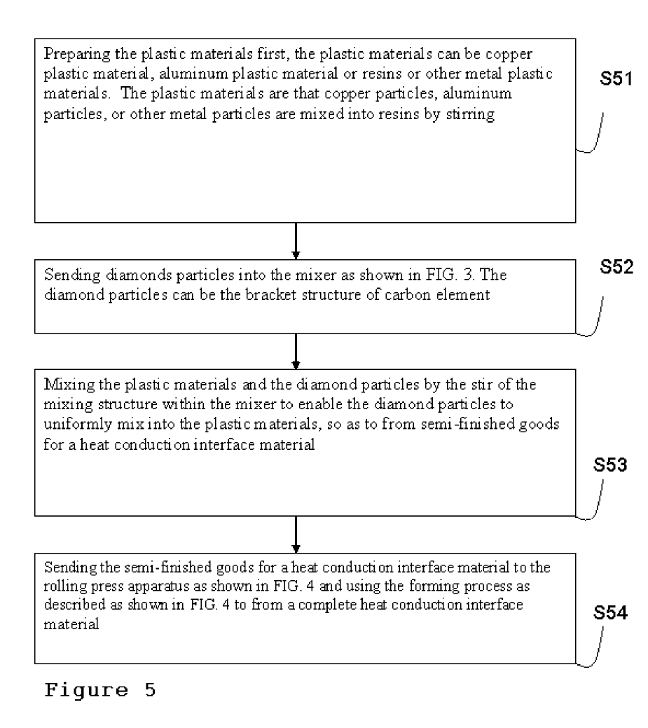

Referring to FIG. 3, a schematic illustrates a mixture forming semi-finished goods for a heat conduction interface material having a plastic material and a bracket structure according to an embodiment of the present invention. A mixer 31 is a gas proof structure and has a first entrance 311, a second entrance 312 and an exit 313. A mixing structure 32 is set into the mixer 31. The process is to prepare a plastic material first. The resins are pressurized to enter the mixer 31 from the first entrance 311, the resins have high temperature resistance and high thermal conductivity like epoxy resins. The mixing structure 32 is activated to stir the resins when the resins are inputted to the mixer 31. Other materials are then inputted to the second entrance 312, the other materials can be copper particles, aluminum particles, or metal particles. Those particles can be uniformly mixed into the resins through the stirring of the mixing structure 32. Therefore, the copper particles are combined with the resins to form copper plastic material, the aluminum particles are combined with the resins to form aluminum plastic material and other metal particles are combined with the resins to form other metal plastic materials. By the way mentioned above, a complete plastic material can be obtained. The diamond particles are then pressurized to input the second entrance 312 to be a bracket structure of carbon element after obtaining the plastic material. The diamond particles are uniformly mixed into the plastic material via the stirring of the mixing structure 32. Lastly, the semi-finished goods for the heat conduction interface material can be acquired.

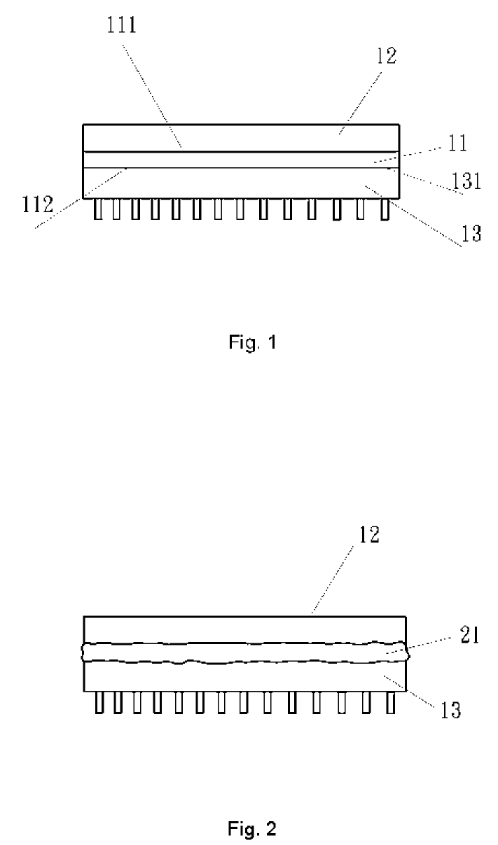

Referring to FIG. 4, a schematic diagram illustrates forming a flat piece of a heat conduction interface material according to an embodiment of the present invention. A rolling press apparatus 41, a horizontal oven 42 and a cutting machine with a plurality of adjusting knives 43 are used in the embodiment. The semi-finished goods for the heat conduction material as shown in FIG. 3 are poured to the rolling press apparatus 41 from the exit 313 of the mixer 31. The surface of the rolling press apparatus 41 needs to be processed with anti-adhesion first to prevent cohering when the semi-finished goods for the heat conduction material are squelching by the rolling press apparatus 41. Afterward the semi-finished goods for the heat conduction material are to from flat shapes that are delivered to the horizontal oven 42 for baking in order to obtain hardened semi-finished goods. Lastly, the harden semi-finished goods are cut by the cutting machine with a plurality of adjusting knives 43 based on demands or sizes which fit any chip. By the way mentioned above, the flat pieces of the heat conduction interface material can be acquired, so as to compose the heat dissipation patch 11 as shown in FIG. 1.

Referring to FIG. 5, a flowchart illustrates a manufacturing process for making a heat conduction interface material according to an embodiment of the present invention. Step S51, preparing the plastic materials first, the plastic materials can be copper plastic material, aluminum plastic material or resins or other metal plastic materials. The plastic materials are that copper particles, aluminum particles, or other metal particles are mixed into resins by stirring. Step S52, sending diamonds particles into the mixer 31 as shown in FIG. 3. The diamond particles can be the bracket structure of carbon element. Step S53, mixing the plastic materials and the diamond particles by the stir of the mixing structure 32 within the mixer 31 to enable the diamond particles to uniformly mix into the plastic materials, so as to from semi-finished goods for a heat conduction interface material. Step S54, sending the semi-finished goods for a heat conduction interface material to the rolling press apparatus 41 as shown in FIG. 4 and using the forming process as described as shown in FIG. 4 to from a complete heat conduction interface material. The decreased efficiency of heat conduction caused by the material characteristics of the buffer interface between the chip and the heat dissipation slip can be improved by providing the heat conduction interface material having a plastic material and a bracket structure of carbon element.

Although the features and advantages of the embodiments according to the preferred invention are disclosed, it is not limited to the embodiments described above, but encompasses any and all modifications and changes within the spirit and scope of the following claims.

What is claimed is:

1. A heat conduction interface material, applied to a buffer interface between a chip and a heat dissipation slip, the characterized in that:
said heat conduction interface material being to enable said heat dissipation slip to stick on a cover surface of said chip, said heat conduction interface material being combined a plastic material and a bracket structure of carbon element.

2. The heat conduction interface material of claim 1, wherein said heat conduction interface material is grease.

3. The heat conduction interface material of claim 1, wherein said heat conduction interface material is a flat piece.

4. The heat conduction interface material of claim 1, wherein said plastic material is copper plastic material.

5. The heat conduction interface material of claim 1, wherein said plastic material is aluminum plastic material.

6. The heat conduction interface material of claim 1, wherein said plastic material is resin.

7. The heat conduction interface material of claim 1, wherein said plastic material is a metal plastic material.

8. The heat conduction interface material of claim 1, wherein said bracket structure of carbon element is diamonds.

9. A method for making a heat conduction interface material, comprising:
employing a mixture to form said heat conduction interface material having a plastic material and a bracket structure of carbon element.

10. The method for making a heat conduction interface material of claim 9, wherein said plastic material is aluminum plastic material.

11. The method for making a heat conduction interface material of claim 9, wherein said plastic material is copper plastic material.

12. The method for making a heat conduction interface material of claim 9, wherein said plastic material is resin.

13. The method for making a heat conduction interface material of claim 9, wherein said plastic material is a metal plastic material.

14. The method for making a heat conduction interface material of claim 9, wherein said bracket structure of carbon element is diamonds.
